(19) United States
(12) Patent Application Publication
(10) Pub. No.: US 2014/0239361 A1
(43) Pub. Date: Aug. 28, 2014

(54) METHODS AND APPARATUS FOR SUPPRESSING CROSS TALK IN CMOS IMAGE SENSORS

(71) Applicant: Semiconductor Manufacturing International (Shanghai) Corporation, (US)

(72) Inventor: Rice Ma, Shanghai (CN)

(73) Assignee: Semiconductor Manufacturing International (Shanghai) Corporation, Shanghai (CN)

(21) Appl. No.: 13/860,429

(22) Filed: Apr. 10, 2013

(30) Foreign Application Priority Data
Feb. 26, 2013 (CN) 201310060959.X

(51) Int. Cl. H01L 27/146

(52) U.S. Cl. CPC H01L 27/14625
USPC 257/292; 438/70

(57) ABSTRACT

A CMOS image sensor with reduced crosstalk includes a semiconductor substrate formed with a plurality of photodiodes formed therein, a dielectric layer formed on the semiconductor substrate, a reflective layer formed on the dielectric layer, and an insulating layer formed on the reflective layer. A plurality of grooves is formed in the dielectric layer, the reflective layer, and the insulating layer above a corresponding photodiode. Each groove is filled with a color filter material to form a color filter above the photodiode. The image sensor also includes a planarization layer formed on the insulating layer and color filter. A microlens is formed on the planarizing layer. The light reflecting layer prevents stray light diffraction line crosstalk into an adjacent photodiode. The color filter grooves confine the target image light only through the filters in the groove window to reach the photodiode.

### CROSS-REFERENCES TO RELATED APPLICATIONS

This application claims priority to Chinese Patent Application No. 201310060959.X, filed Feb. 26, 2013, commonly owned and incorporated by reference herein for all purposes.

### BACKGROUND OF THE INVENTION

The present invention relates to the field of semiconductors technology, and more particularly to a CMOS image sensor and its preparation method.

Compared with the traditional image sensor technology, CMOS image sensor technology provides better quality and has gained wide use. A conventional CMOS image sensor usually includes a semiconductor having a plurality of photodiodes in a substrate, a dielectric layer on the semiconductor substrate, a filter above the dielectric layer, a microlens above the filter, and an insulating layer above the microlens.

Even though widely used, such conventional CMOS image sensors suffer from a number of limitations. For example, stray light can reach a photodiode through reflection or diffraction of light through the gaps between the microlenses. The stray light can degrade the quality of the sensed images.

Conventional methods for reducing stray light include forming a concave lens between adjacent microlenses. The concave lens is formed by forming a trench between adjacent microlenses and filling it with an insulating material. Such a concave lens can redirect the stray light to the microlenses and enter the photodiode. However, such a solution increases cost and complexity of the manufacturing process and provide only limited remedy.

Accordingly, there is a need for improving the quality of the images formed by CMOS image sensors.

### BRIEF SUMMARY OF THE INVENTION

Embodiments of the present invention provide techniques related to image sensors. More particularly, embodiments of the present invention provide a method and device structure for forming a color filter groove to direct light from the microlens to the photodiode to reduce stray light. The light reflecting layer between the filter grooves prevents stray light diffraction line crosstalk into an adjacent photodiode. By confining the target image light only through the color filters in the groove window to reach the photodiode, the imaging quality of the CMOS image sensor can be improved. Merely by way of example, the present invention has been applied to CMOS image sensor, but it would be recognized that the invention has a much broader range of applications.

In accordance with some embodiments of the present invention, a CMOS image sensor includes a semiconductor substrate having a plurality of photodiodes formed therein, a dielectric layer formed on said semiconductor substrate, a reflective layer formed on said dielectric layer, and an insulating layer formed on said reflective layer. The image sensor also includes a plurality of grooves extending through the insulating layer, the reflective layer, and the dielectric layer to form a plurality of grooves. Each groove exposes a surface of the substrate. The image sensor also has a plurality of color filters, with a color filter material in each groove forming a color filter above each photodiode. A planarization layer is formed on the insulating layer and the filter material. The CMOS sensor also has a plurality of microlenses formed on the planarization layer.

In some embodiments of the image sensor, a protective layer is formed between the color filter material and a surface of each groove. In a specific embodiment, the protective layer includes a nitride material. In another embodiment, the reflective layer comprises a metal layer between adjacent microlenses for shielding stray light. In another embodiment, a cross-sectional area of the microlens is greater than a cross-sectional area of the color filter. In another embodiment, a cross-sectional area of the color filter is greater than a cross-sectional area of the photodiode. In some embodiments, each of the filters is configured to pass red, green, or blue light.

In some embodiments of the image sensor, a red color filter material is disposed in a first groove, a green color filter material is disposed in a second groove, and a blue color filter material is disposed in a third groove. In some embodiments, the second groove is adjacent to the first groove, and the third groove is adjacent to the second groove. In another embodiment, the photodiode includes an epitaxially grown silicon layer formed on a P-type silicon substrate, and an N type doped region formed in the epitaxial layer. In some embodiments, the image sensor also includes a transistor gate adjacent to the groove, and the gate is disposed between the N type doped region in the photodiode and an N+ doped region.

In accordance with another embodiment of the present invention, a method for forming a CMOS image sensor includes providing a semiconductor substrate including a plurality of photodiodes, forming a dielectric layer on the semiconductor substrate, forming a reflective layer on the dielectric layer, and forming an insulating layer on the reflective layer. The method also includes patterning a mask layer on the insulating layer and etching the insulating layer, the reflective layer, and the dielectric layer to form a plurality of grooves. Each groove exposes a surface of the substrate. The method also includes removing the mask layer and forming a color filter material in each of the grooves to form a corresponding plurality of filters. Each filter is disposed above a corresponding photodiode. The method further includes forming a planarization layer on the insulating layer and the filters, and forming a plurality of microlenses on the planarization layer.

In another embodiment, the method also includes forming a protective layer lining a surface of each of the grooves before forming the filter material, and forming the filter material on the protective layer inside the grooves. In another embodiment of the method, the etching step includes using ion etching. In another embodiment, the reflecting layer includes a metal layer. In another embodiment, forming a color filter material in each of the grooves includes using a spin coating process. In another embodiment, forming a color filter material in each of the grooves includes using a deposition process. In some embodiments, a cross-sectional area of the microlens is greater than a cross-sectional area of the filter. In some embodiments, a cross-sectional area of the filter is greater than a cross-sectional area of the photodiode. In another embodiment, each of the filters is configured to pass red, green, or blue light. In another embodiment, a red color filter material is disposed in a first groove, a green color filter material is disposed in a second groove, and a blue color filter material is disposed in a third groove.

Various additional embodiments, features, and advantages of the present invention can be more fully appreciated with reference to the detailed description and accompanying drawings that follow.

### BRIEF DESCRIPTION OF THE DRAWINGS

The present invention will be described in the following exemplary embodiments with the accompanying drawings in which:

FIG. 1 shows a cross-sectional view of a CMOS image sensor according to an embodiment of the present application;

FIG. 2 shows a process flow diagram illustrating a method of forming a CMOS image sensor according to an embodiment of the present application; and

FIGS. 3A to 3D shows cross-sectional diagrams illustrating a method of forming a CMOS image sensor according to an embodiment of the present application.

### DETAILED DESCRIPTION OF THE INVENTION

The following detailed description is illustrative and is intended to provide further explanation of the present invention. Unless otherwise specified, all technical and scientific terms used herein have the same meaning as commonly understood by those having ordinary skill in the technical field of the present invention.

It should also be noted that the technical terms as used herein to describe a specific embodiment, and not intended to limit the exemplary embodiment according to the present invention. For example, the use of singular forms, unless explicitly noted otherwise, is also intended to include plural forms. In addition, when used in this specification, “comprising” and/or “including”, specifies the presence of features, steps, operations, devices, components and/or combinations thereof.

In order to facilitate the description, spatial relative terms used herein, such as “over”, “above”, “on top of”, etc., are used to describe a device or feature as shown in the drawings relative to spatial positions of other devices or features. It should be understood that the spatially relative terms are intended to encompass different orientations in use or operation in addition to the orientation of the device as described in the drawings. For example, if the device in the figures is inverted, the description such as “on top of the other device or construct” or “above the other device or construct” will be understood as “in the bottom of the other device or construct” or “under the other device or construct.” Thus, the exemplary term “above” may include both an orientation of “above” and “below.” The device can also be oriented differently (rotated 90 degrees or at other orientations), but will be interpreted relative to the descriptors used herein.

In order to obtain a better image quality, the inventors of the present invention have conducted research on the existing structure of the CMOS image sensors, and found that in conventional CMOS image sensors, the light encounters metal wiring in the optical path and can undergo diffraction leading to signal crosstalk between the adjacent pixels. In a CMOS sensor, the photodiodes collect light to form an image. Signal crosstalk is caused by the incidental light from the target passes the microlens or the gap that results in irregular stray light or diffracted light by the filter, the dielectric layer, or by the reflection or diffraction of the metal structures in the dielectric layer entering adjacent pixel points. Signal crosstalk is an important factor that causes deterioration of image quality.

However, the dielectric layer and the metal wiring that is disposed between the semiconductor substrate and the color filter is essential components of the CMOS image sensor device. Therefore, it is important to resolve signal crosstalk caused by light diffraction, and refraction caused by the metal structure in the dielectric layer of a pixel point into adjacent pixels which causes deterioration of the image quality. Embodiments of the present invention provide methods and apparatus for reducing signal crosstalk in CMOS image sensors.

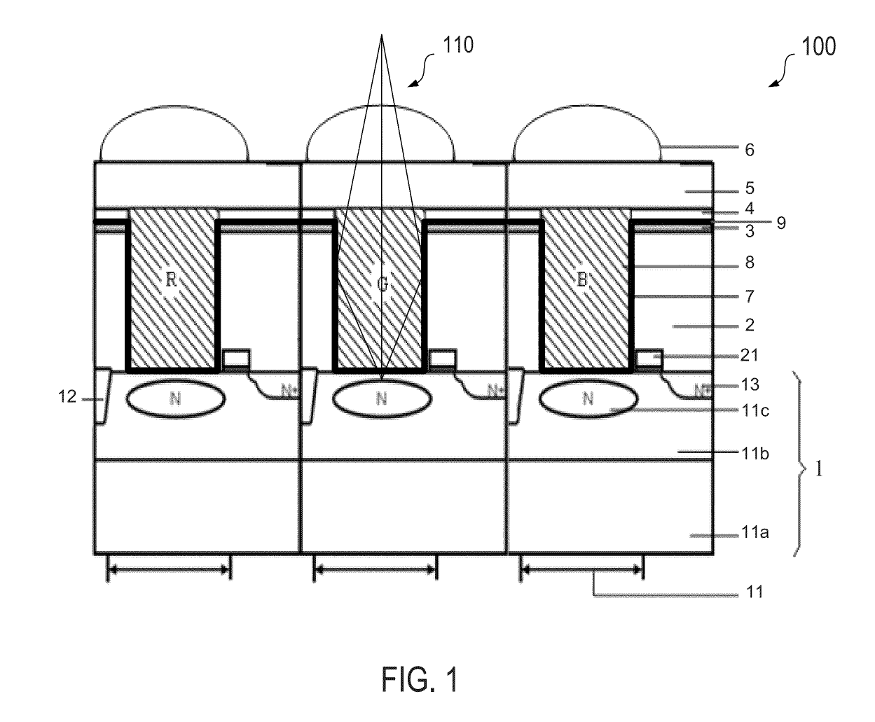

FIG. 1 shows a cross-sectional view of a CMOS image sensor according to an embodiment of the present invention. As shown image sensor 100 includes a semiconductor substrate 1, a dielectric layer 2, a reflective layer 3, an insulating layer 4, a planarization layer 5, microlenses 6, and a plurality of filter grooves 7 filled with filter material 8. A plurality of photodiodes 11 is formed in semiconductor substrate 1. Dielectric layer 2 is formed on semiconductor substrate 1. Reflective layer 3 is formed on dielectric layer 2. Insulating layer 4 is formed on reflective layer 3. Planarization layer 5 is formed on insulating layer 4. Microlenses 6 are formed on planarization layer 5. A plurality of filter grooves 7 filled with color filter material 8 is formed in dielectric layer 2 and extending through reflective layer 3 and insulating layer 4. Each microlens 6 is disposed over a color filter groove 7 above a corresponding photodiode 11.

In embodiments of the present invention, reflective layer 3 is provided on dielectric layer 2 to prevent stray light and diffraction light from entering adjacent photodiodes. Only the light of the target image can enter through a specific window channel between adjacent reflective layer 3. As shown in FIG. 1, the open windows in reflective layer 3 are aligned to grooves filled with a color filter material, which forms color filters 8. Filters 8 are provided in dielectric layer 2 and are set in grooves 7, so that filters 8 are disposed directly on photodiode 11 in semiconductor substrate 1. Therefore, the light 110 passing through the color filter can enter directly into photodiode 11 without passing through the dielectric layer, reducing the effect of the crosstalk generated due to reflection or diffraction caused by metal connection structures in the dielectric layer. Color filters 8, therefore, provides an effective light guide similar to an optical fiber. In some embodiments, the color filter is also capable of absorbing the light from adjacent pixels through reflection by the metal structures in the dielectric layer and reduce crosstalk on the photodiode. Further, the reflective layer 3 between adjacent grooves is configured to shield stray light from entering the photodiodes.

In the present application, light reflecting layer 3 may utilize any material having a reflective effect, as long as it does not affect the image sensing function of the CMOS image sensor. In some embodiments, light reflecting layer 3 can include a metal material. In some embodiments, the last layer of metal wiring, for example, in the CMOS circuit, can be used as the light reflecting layer, thus reducing production costs.

As shown in FIG. 1, in some embodiments of the present invention, the filter is provided with a protective layer 9 formed on the surface of the groove 7. Color filter material 8 is formed on protective layer 9. Preferably, the protective layer includes layer of nitride. Nitride protective layer materials include but are not limited to SiN. Protective layer 9 can serve as a protection layer of the various layers of material during the fabrication process. In alternative embodiments, no protective layer is formed in the grooves.

In CMOS image sensors, the microlenses focus light to the center of the photodiode. In embodiments of the present invention, the microlenses and the filters are aligned to the photodiodes. The optical filter provided with the grooves and the microlenses are sequentially formed over the photodiodes.

In embodiments of the present invention, the color filters can include red filters, green filters, or blue filters. Depending on the application, the red filters, green filters, or blue filters can be disposed on the respective photodiodes. In some embodiments, different color filters are disposed on photodiodes for adjacent pixels.

In FIG. 1, semiconductor substrate 1 may be a polycrystalline silicon substrate or a single crystalline silicon substrate. For example, an epitaxially grown silicon layer 11b can be formed on a P-type silicon substrate 11a. Then, an N type doped region 11c is formed in the epitaxial layer 11b, thereby forming the photodiode structure 11. Semiconductor substrate 1 can further include source and drain regions (not shown), shallow trench isolation regions (STI) 12 to isolate the grooves, as well as an N+ doped portion 13, and the like. The dielectric layer can include multiple-layer metal wiring layers and one or more transistors 21. In some embodiments, transistor 21 may surround the filter groove 7. As shown in FIG. 1, transistor 21 has a gate that is adjacent to groove 7 and is configured to control current flow between N type doped region 11c of the photodiode and the N+ doped portion 13.

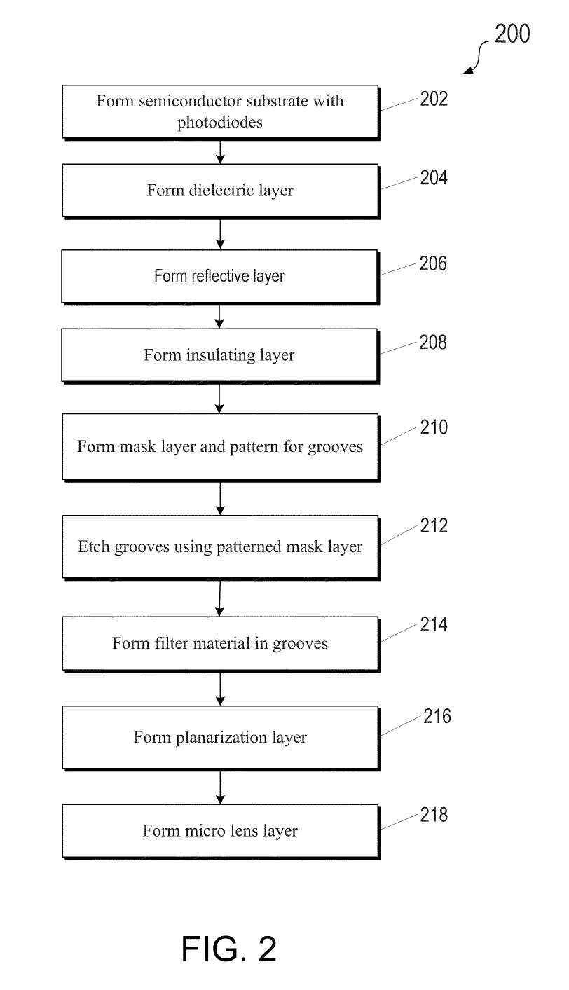

FIG. 2 shows a process flow diagram of a method of forming a CMOS image sensor according to an embodiment of the present application. The processes in the method are outlined in the flow chart with reference to the device structure in FIG. 1. As shown in FIG. 2, method 200 includes providing a semiconductor substrate 1 having a plurality of photodiodes 11 formed therein (202). The method includes forming a dielectric layer 2 on the semiconductor substrate 12 (204). Forming a reflective layer 3 on the dielectric layer 2 (206), and forming an insulating layer 4 on the reflective layer 3 (208). The method also includes forming a mask layer is on insulating layer 4 and patterned the mask layer for forming grooves (210). Etching is carried out sequentially to etch insulating layer 4, light reflective layer 3, and dielectric layer 2 to reach semiconductor substrate 1 to form groves 7 for the filters (212). After the mask layer is removed (not shown in FIG. 2), the grooves are filled with optical filter material 8 (214). The planarizing layer 5 is formed on the insulating layer 4 and filter 8 (216). Subsequently, micro-lenses 6 are formed on the planarizing layer 5 (218).

As described above, the filters are provided directly on the semiconductor substrate 1. In some embodiments, adjacent filters are disposed to allow different wavelengths of light to pass, such that only a specific wavelength of light can be passed through the filter into the corresponding photodiode, reducing the chance of crosstalk generated. With the color filters protecting the photodiodes, the light transmitted through the adjacent pixels are filtered, thereby reducing crosstalk effects and improving the imaging sensitivity.

In some embodiments, a protective layer is formed on the surface of each groove. In some embodiments, the protective layer is conducive to improve the quality and yield of the CMOS image sensor. In some embodiments, the protective layer can be a layer of nitride, for example, SiN.

In some embodiments, the grooves are formed by plasma etching methods. In some embodiments, the reflective layer is a metal layer. For example, metal layers for the interconnect structure in a dielectric layer can be used to form the reflective layer. Such a method can be implemented in a standard CMOS IC process without incurring additional cost and complexity.

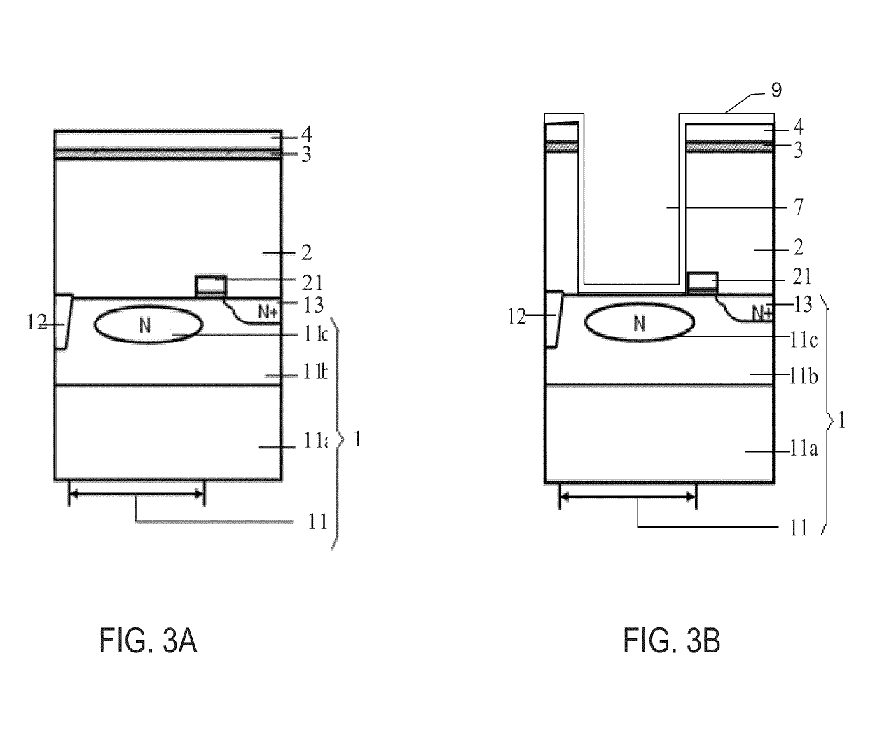

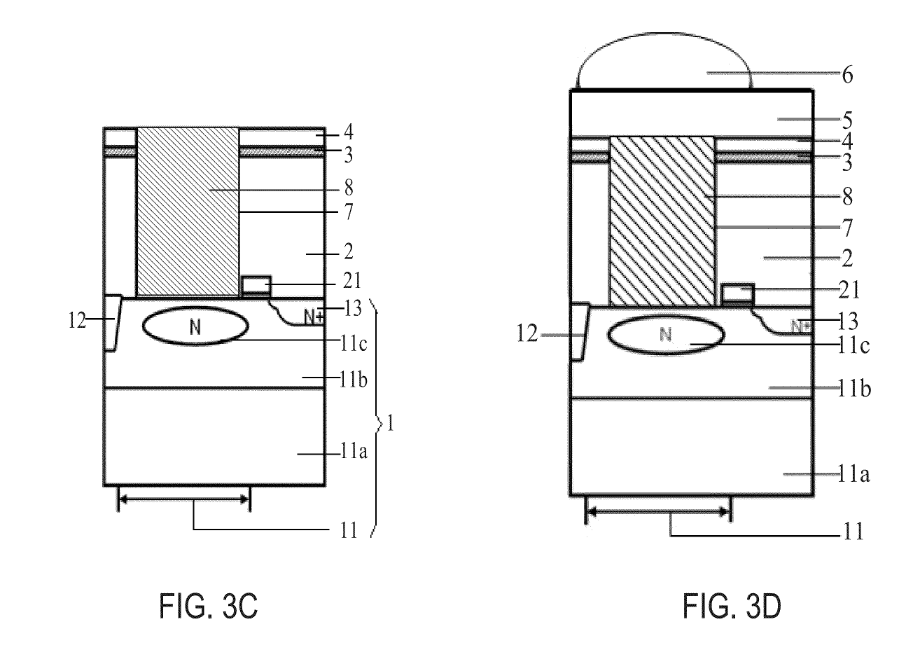

FIGS. 3A to 3D show cross-sectional diagrams illustrating further details of the method of forming a CMOS image sensor according to an embodiment of the present application.

As shown in FIG. 3A, a plurality of photodiodes 11 are formed in semiconductor substrate 1. A dielectric layer 2 is formed on semiconductor substrate 1. A reflective layer 3 is formed on the dielectric layer 2, and an insulation layer 4 is formed on reflective layer 3 layer.

In some embodiments, the semiconductor substrate 1 may be a polycrystalline silicon substrate or a crystalline silicon substrate. For example, an epitaxially grown silicon layer 11b can be formed on a P-type silicon substrate 11a. Then, an N type doped region 11c is formed in the epitaxial layer 11b, thereby forming the photodiode structure 11. The semiconductor substrate 1 further include source and drain regions (not shown), shallow trench isolation regions (STI) 12 to isolate the grooves, as well as an N+ doped portion 13, and the like. There layers and doped regions can be formed using conventional integrated circuit processes.

In some embodiments, dielectric layer 2 includes a layer of insulating material. The dielectric layer can also include multiple-layer metal wiring layers and one or more transistors 21. In some embodiments, transistor 21 may surround the filter groove 7. In this embodiment, the light reflective layer 3 can be formed with a metal material, for example, using the last layer of metal wiring, to reduced production costs. Insulating layer 4 can be the same material as the layer material of the dielectric layer 2, or a different insulating material having a low dielectric constant, for example, SiO2.

As shown in FIG. 3B, groove 7 is formed by first forming a patterned mask layer (not shown) on insulating layer 4 with an opening directly above photodiode 11 in semiconductor substrate 1. An etching process is carried out to etch insulating layer 4, reflective layer 3, and dielectric layer 2 to reach the semiconductor layer 1 to form filter groove.

As shown in FIG. 3B, in some embodiments of the present invention, the filter is provided with a protective layer 9 formed on the surface of the groove 7. In some embodiments, the protective layer includes a nitride material, including but are not limited to SiN. Protective layer 9 can serve as a protection layer of the various layers of material during the fabrication process. In alternative embodiments, no protective layer is formed in the grooves, such as shown in FIGS. 3C and 3D.

As shown in FIG. 3C, after the mask is removed, groove 7 is filled with color filter material 8 to form the color filter. In embodiments with a protective layer 9, color filter material 8 is formed on the protective layer 9. In embodiments without a protective layer, color filter material 8 is formed on the surface of groove 7. In conventional color filter technology, the color filter film can be included a photosensitive material, which facilitates patterning, and pigment or dye that provides the color filtering function. In embodiments of the present invention, conventional color filter materials can also be used. For example, a color filter material can be deposited or spin coated on the substrate surface to fill the grooves. Then, a patterning process can be used to retain the color filter material in the desired grooves. For example, grooves for adjacent pixels can have different colors, such as red, green, or blue. In some embodiments, the deposition and patterning of color filter material is carried out for each color. Alternatively, in embodiments of the invention, an etching process can be used to selectively form color filter material in desired grooves. Further, in some embodiments, a polishing process can also be used to remove excess color filter material outside the grooves.

FIG. 3D shows that a planarizing layer 5 is formed on the insulating layer 4 and color filter 8. A microlens 6 is then formed on planarizing layer 5. It can be seen that groove 7 is aligned with photodiode 11 and microlens 6. The layers and structures described above can be formed using conventional integrated circuit processes.

In embodiments of the present invention, light reflective layer 3 is provided on the dielectric layer 2 to avoid stray light diffraction line directly enter into an adjacent photodiode to cause crosstalk. Each photodiode is configured to receive light only from the target image through a specific window channel, that is, in the color filter after filtration. Meanwhile, the filter is provided in groove 7, so that filter 8 is disposed directly on semiconductor substrate 1, which allows the light to pass through the color filter and directly enter into photodiode 11. In this arrangement, the light does not need to go through dielectric layers which may include interconnect structures that may cause crosstalk through reflection or diffraction. Further, color filter 8 in groove 7 can provide an optical guide effect to direct the propagation of the light similar to that of an optical fiber. In some embodiments, the color filter material is chosen to have a refractive index to facilitate total internal reflection with respect to the adjacent dielectric layer or the protective layer. In some embodiments, the color filter is also capable of absorbing light from adjacent pixels, and to avoid the impact of the crosstalk on the photodiode.

It should be understood that embodiments of the present invention described herein are provided by way of example only and that numerous substitutions, variations, and modifications can be made without departing from the spirit and scope of the invention. Thus, the breadth and scope of the present invention should not be limited by any of the above-described exemplary embodiments, but should be defined only in accordance with the following claims and their equivalents.

1. A CMOS image sensor, comprising:
a semiconductor substrate including a plurality of photodiodes formed therein;
a dielectric layer formed on said semiconductor substrate;
a reflective layer formed on said dielectric layer;
an insulating layer formed on said reflective layer;
a plurality of grooves extending through the insulating layer, the reflective layer, and the dielectric layer to form a plurality of grooves, each groove exposing a surface of the substrate;
a color filter material in each groove forming a color filter above each photodiode;
a planarization layer formed on the insulating layer and the color filter material; and
a plurality of microlenses formed on the planarization layer;

2. The image sensor according to claim 1, further comprising a protective layer between the color filter material and a surface of each groove.

3. The image sensor according to claim 2, wherein said protective layer comprises nitride.

4. The image sensor according to claim 1, wherein said reflective layer comprises a metal layer.

5. The image sensor according to claim 1, wherein a cross-sectional area of the microlens is greater than a cross-sectional area of the color filter.

6. The image sensor according to claim 1, wherein a cross-sectional area of the color filter is greater than a cross-sectional area of the photodiode.

7. The image sensor according to claim 1, wherein each of the filters is configured to pass red, green, or blue light.

8. The image sensor according to claim 1, wherein a red color filter material is disposed in a first groove, a green color filter material is disposed in a second groove, and a blue color filter material is disposed in a third groove, wherein the second groove is adjacent to the first groove, and the third groove is adjacent to the second groove.

9. The image sensor according to claim 1, wherein the photodiode comprises an epitaxially grown silicon layer formed on a P-type silicon substrate, and an N-type doped region formed in the epitaxial layer.

10. The image sensor according to claim 9, further comprising a transistor gate adjacent to the groove and disposed between the N-type doped region in the photodiode and an N+ doped region.

11. A method for forming a CMOS image sensor, comprising:
forming a semiconductor substrate including a plurality of photodiodes;
forming a dielectric layer on the semiconductor substrate;
forming a reflective layer on the dielectric layer;
forming an insulating layer on the reflective layer;
patterning a mask layer on the insulating layer;
etching the insulating layer, the reflective layer, and the dielectric layer to form a plurality of grooves, each groove exposing a surface of the substrate;
removing the mask layer;
forming a color filter material in each of the grooves to form a corresponding plurality of color filters, each color filter being disposed above a corresponding photodiode;
forming a planarization layer on the insulating layer and the color filters; and
forming a plurality of microlenses on the planarization layer.

12. The method according to claim 11, further comprising:
forming a protective layer lining a surface of each of the grooves before forming the color filter material; and
forming the color filter material on the protective layer inside the grooves.

13. The method according to claim 11, wherein the etching step comprises using ion etching.

14. The method according to claim 11, wherein said reflecting layer comprises a metal layer.

15. The method, according to claim 11, wherein forming a color filter material in each of the grooves comprises using a spin coating process.

16. The method according to claim 11, wherein forming a color filter material in each of the grooves comprises using a deposition process.

17. The method according to claim 11, wherein a cross-sectional area of the microlens is greater than a cross-sectional area of the filter.

18. The method according to claim 11, wherein a cross-sectional area of the filter is greater than a cross-sectional area of the photodiode.

19. The method according to claim 11, wherein each of the filters is configured to pass red, green, or blue light.

20. The method, according to claim 11, wherein a red color filter material is disposed in a first groove, a green color filter material is disposed in a second groove, and a blue color filter material is disposed in a third groove.
